(19) United States
(12) Patent Application Publication
(10) Pub. No.: US 2014/0232472 A1
(43) Pub. Date: Aug. 21, 2014

(54) Method and Device for Protecting a High-Frequency Power Amplifier Against a Termination fault

(71) Applicants: Abdel-Messiah Khilla, Backnang (DE); Juergen Schaeufler, Backnang (DE)

(72) Inventors: Abdel-Messiah Khilla, Backnang (DE); Juergen Schaeufler, Backnang (DE)

(73) Assignee: Tesat-Spacecom GmbH & Co. KG, Backnang (DE)

(21) Appl. No.: 14/128,957

(22) PCT Filed: Jun. 18, 2012
(86) PCT No.: PCT/DE2012/000625

§ 371 Date: Mar. 14, 2014

(30) Foreign Application Priority Data
Jun. 27, 2011 (DE) 10 2011 106 234.7

(51) Int. Cl. H03F 1/52; H03F 3/193; H03F 3/21; H03F 1/56

(52) U.S. Cl. CPC H03F 1/523; H03F 1/56; H03F 3/193; H03F 3/21; H03F 2200/444; H03F 2200/387; H03F 2200/451; H03F 2203/21
USPC 330/298

(57) ABSTRACT

A mismatch protection circuit for high frequency power amplifiers includes a waveguide coupler connected to the output of the high frequency power amplifier. The waveguide coupler includes a first detector diode, which supplies, according to the power level being applied, a first voltage, which corresponds to the effective power that is fed in. The waveguide coupler also includes a second detector diode, the outputted second voltage of which corresponds to the power that is reflected due to the mismatch. The protection circuit further includes a control circuit, with which the amount of a mismatch is determined from the difference between the voltage value at the second diode and a reference voltage. The output stage(s) of the high frequency power amplifier(s) is and/or are switched on or off, depending on whether the voltage difference drops below or exceeds a given reference value.

### FIELD OF THE INVENTION

Exemplary embodiments of the present invention relate to a mismatch protection circuit for high frequency power amplifiers in the event that an impedance mismatch occurs on the output side.

### BACKGROUND OF THE INVENTION

High frequency power amplifiers in a waveguide system are designed to have a specified impedance of, for example, 50 Ohms. In order to guarantee an uninterrupted function of the power amplifier and a maximum power output in the subsequent following system, such as an antenna busbar, the following system has to exhibit the same line impedance as the power amplifier.

In the event that the impedances at the connecting point are different, the results are reflections, by means of which a part of the power output is transmitted back into the amplifier output stage. In the highly critical event of a faulty connection, i.e. an open circuit or a short circuit, the total high frequency power output of the amplifier is transmitted back into the amplifier.

Such an event can occur during the startup or during measurements of such amplifiers due to operating and/or handling errors.

High frequency power amplifiers, the output stages of which are designed with transistors, can be thermally loaded by the reflected power output components of the amplifier in such a way that the semiconductor components are damaged or even destroyed.

In order to protect such output stages against the reflected power outputs in the event of a faulty termination, the current trend is to mount circulators on the output of a high frequency transistor power amplifier. This arrangement is shown in FIG. 1 by means of an example of an output section of a power amplifier with parallel output stages.

The circuits, which are designed as three ports, have a direction dependent waveguide. The power, fed into the port 1, is transmitted with low loss to the port 2. The power, which is fed into the port 2, or more specifically the power that is reflected from said port, in the event of a faulty termination of the RF output, is passed on to the port 3. By terminating the port 3 with a load resistor having the size of the reference system, the entire power output to the port 3 is absorbed and is not reflected again from the port 3 to the port 1. A circulator, which comprises a third port that is terminated with a load resistor, acts as an isolator.

### SUMMARY OF THE INVENTION

In recent years new transistors have been developed on the basis of gallium nitride for use in high frequency power amplifiers. These transistors have output powers of up to 200 watts. Since they simultaneously also have very high efficiency, they lend themselves well to a usage in power amplifiers for satellite applications. However, at the same time a low loss of the output networks downstream of the power amplifier is required so as not to adversely effect the efficiency of the amplifier in satellite application. Furthermore, small sizes and low weights of the devices are necessary.

In order to protect such power amplifiers against the reflected power outputs in the event of a faulty termination, isolators would be necessary so that their terminating resistor at the third port can absorb the full power of up to 200 watts. Such insulators cannot be implemented in the high frequency range with the simultaneously required low loss and small size.

Exemplary embodiments of the present invention are directed to addressing a mismatch in high frequency power amplifiers of the type under discussion herein.

### BRIEF DESCRIPTION OF THE DRAWING FIGURES

The invention is described in detail below with reference to the drawings, in which

FIG. 1 shows the state of the art with a circulator.

FIG. 2 shows the basic circuit of a mismatch detector.

FIG. 3 shows the coupling loss and isolation (sharp directivity) of the coupler.

FIG. 4 shows a mismatch protection circuit according to the invention; and

FIG. 5 shows an output combiner of two parallel output stages with a mismatch protection circuit.

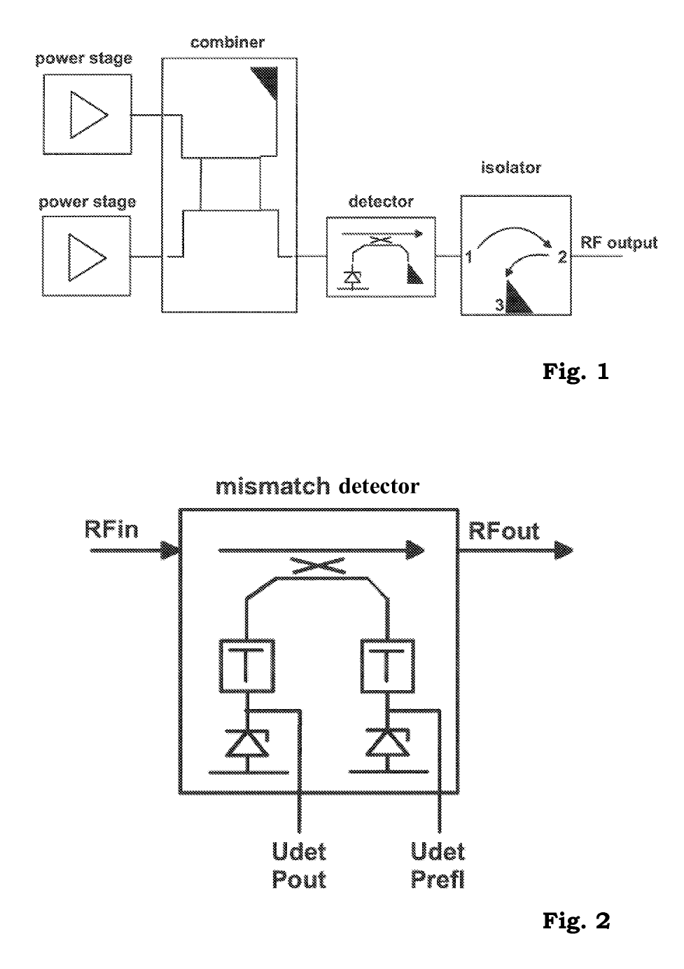

### DETAILED DESCRIPTION

The inventive mismatch protection circuit for high frequency power amplifiers has a detector, which is mounted on the output of the power amplifier. This detector is designed as a waveguide coupler; and its port, which is decoupled in the throughput direction, is terminated with a load resistor. Since this port for the reflected waves from the output has a lower coupling loss than the power fed in for the output stages, this port is also terminated with a detector diode (FIG. 2).

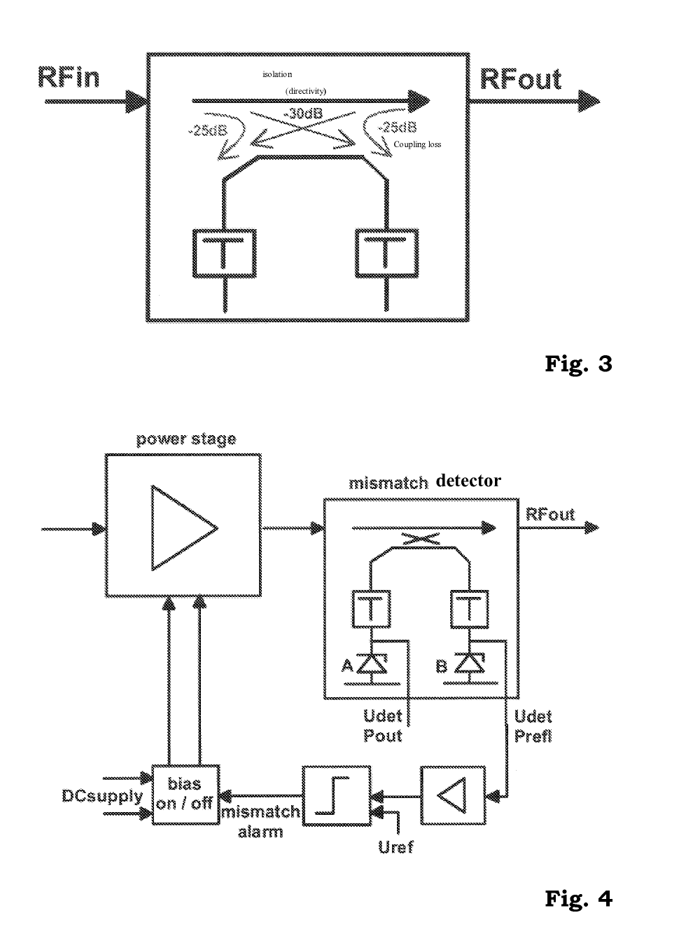

The coupler is designed in terms of its size in such a way that it is guaranteed that the coupling loss of, for example 25 dB, in the respectively coupled port is less than the coupling loss of, for example, −30 dB in the respectively decoupled port (see FIG. 3). As a result, the conditions for a clear and unambiguous distinguishability between the origin of the signal levels, being applied to both detector diodes, and the allocation of the signal levels to the detector diodes are met.

The voltages, which are supplied by the two detector diodes and which are proportional to the respective power levels being applied, are further processed in the control circuits.

The voltage, which is supplied by the diode A, corresponds to the effective power fed into the output. This effective power will continue to be used in the control circuit, in order to hold the output power constant, for example, in the ALC mode, and/or by means of the temperature or in order to be transmitted, as the telemetry data, to the system to be monitored.

The voltage, which is supplied by the diode B, is proportional to the power that is reflected at the output of the power amplifier owing to the termination with a non-ideal impedance. It is clear from FIG. 4 that this voltage may be fed in analog or digital form into the circuit after suitable amplification and/or conditioning; and that this circuit switches the output stage on and off. When a predefined level Uref is exceeded, a mismatch alarm has the effect that the output stage is rapidly switched off.

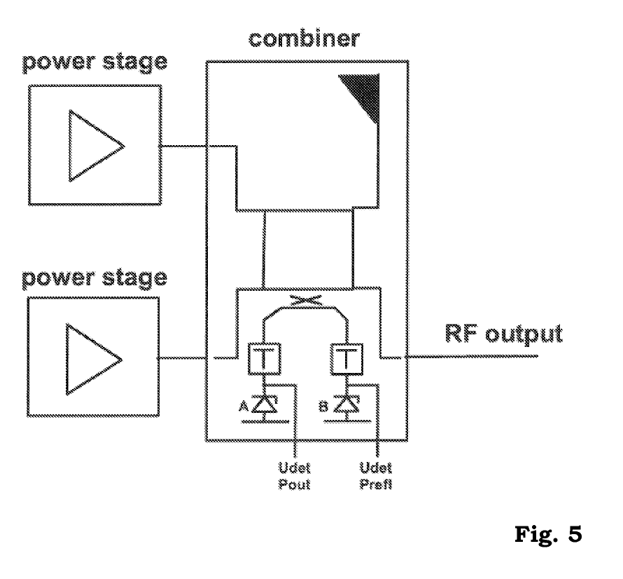

In the event of parallel output stages, which is a common occurrence, these output stages are combined by means of a coupler that is used as an adder. This coupler is usually implemented as a branch line coupler in power strip technology for reasons relating to low loss. In this case the mismatch coupler, as shown in FIG. 5, can be integrated in this coupler, as a result of which the throughput losses of the whole arrangement can be reduced even more, while at the same time both the classical telemetering of the RF output power as well as the mismatch protection can be implemented.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

1-15. (canceled)

16. A method for protecting a high frequency power amplifier having a high output power and a high efficiency against a termination fault, wherein a mismatch protection circuit is connected to the high frequency power amplifier on the output side, the method comprising:
deriving a first voltage, which is proportional to a power level applied to a first detector diode, from the first detector diode of the mismatch protection circuit, wherein the first voltage corresponds to an effective power fed into the output;
deriving a second voltage, which is proportional to a power level applied to a second detector diode, from the second detector diode of the mismatch protection circuit, wherein the second voltage corresponds to a reflected power;
transmitting the first and second derived voltages are transmitted to a control circuit; and
switching on or off, by the control circuit, an output stage of the high frequency power amplifier depending on whether a specified reference voltage is exceeded or undershot by the second voltage derived from the second diode.

17. The method as claimed in claim 16, wherein the mismatch protection circuit comprises a waveguide coupler having a port that is decoupled in a throughput direction and that is terminated with a load resistor.

18. The method as claimed in claim 16, wherein the waveguide coupler is configured in such a way that a coupling loss in a respectively coupled port is less than a coupling loss in a respectively decoupled port, so that single levels applied to the first or second detector diode are derived.

19. The method as claimed in claim 16, wherein the effective power fed into the output corresponds to a voltage supplied by the first diode and is used in an ALC mode, by means of the temperature to keep an output power of the amplifier constant, or to control, as telemetry data, a monitoring system.

20. The method as claimed in claim 16, wherein the second voltage supplied by the second diode corresponds to the power reflected at the output of the power amplifier due to the termination fault.

21. The method as claimed in claim 16, wherein after suitable amplification or conditioning, the second voltage supplied by the second diode is fed in analog or digital form into the mismatch protection circuit, in order to switch off the output stage as soon as the specified reference level is exceeded.

22. The method as claimed in claim 16, wherein the high frequency power amplifier has two parallel output stages, the method further comprising:
combining, by an adder, outputs of the two parallel output stages, wherein adder acts as a coupler and the mismatch protection circuit is integrated into the coupler.

23. A circuit for protecting a high frequency power amplifier having a high output power and a high efficiency against a termination fault, the circuit comprising:
a waveguide coupler, which is connected to an output of the high frequency power amplifier, wherein the waveguide coupler comprises
a first detector diode configured to supply, according to a power level applied to the first detector diode, a first voltage corresponding to an effective power that is fed to the first detector diode; and
a second detector diode configured so that an outputted second voltage of the second detector diode corresponds to power that is reflected due to a mismatch;
a control circuit configured to determine an amount of the mismatch using a difference between the outputted voltage value of the second detector diode and a reference voltage, and the control circuit is configured to switch on or off an output stage of the high frequency power amplifier, depending on whether the amount of the mismatch drops below or exceeds a given reference value.

24. The protection circuit as claimed in claim 23, wherein the first voltage supplied by the first detector diode corresponds to an effective power that is fed into the output, wherein control circuit is configured to use the effective power in order to hold constant the output power of the amplifier in an ALC mode, by means of the temperature to keep an output power of the amplifier constant, or to control, as telemetry data, a monitoring system.

25. The protection circuit as claimed in claim 23, wherein second voltage supplied by the second detector diode is proportional to the power that is reflected at the output of the power amplifier due to a termination with a non-ideal impedance.

26. The protection circuit as claimed in claim 23, wherein after a corresponding amplification or conditioning, the second voltage supplied by the second detector diode is fed in analog or digital form into the protection circuit and, on exceeding a predefined level switches the output stages on or off.

27. The protection circuit as claimed in claim 23, wherein a port of the waveguide coupler that is decoupled in a throughput direction is terminated with a load resistor.

28. The protection circuit as claimed in claim 23, wherein a port that is decoupled in a throughput direction and that is configured for the reflected waves from the output of the power amplifier has a lower coupling loss than for the power that is fed in from the output stages.

29. The protection circuit as claimed in claim 23, wherein the high frequency power amplifier has two output stages and the protection circuit further comprises:
a coupler, configured as an adder, coupled to outputs of the two output stages and configured to combine the outputs of the two output stages and the mismatch protection circuit is integrated into the coupler.

30. The protection circuit as claimed in claim 29, wherein the coupler is a branch line coupler.
